(19) United States
(12) Patent Application Publication
(10) Pub. No.: US 2022/0020905 A1
(43) Pub. Date: Jan. 20, 2022

(54) SEMICONDUCTOR LIGHT EMITTING DEVICE

(71) Applicant: STANLEY ELECTRIC CO., LTD., Tokyo (JP)

(72) Inventor: Minoru TANAKA, Tokyo (JP)

(73) Assignee: STANLEY ELECTRIC CO., LTD., Tokyo (JP)

(21) Appl. No.: 17/376,317

(22) Filed: Jul. 15, 2021

(30) Foreign Application Priority Data
Jul. 20, 2020 (JP) 2020-123907

(51) Int. Cl. H01L 33/62; H01L 33/48; H01L 33/54; H01L 33/38

(52) U.S. Cl. CPC H01L 33/62; H01L 33/382; H01L 33/54; H01L 33/483

(57) ABSTRACT

A semiconductor light emitting device has: a semiconductor light emitting element; a substrate on which the semiconductor light emitting element is mounted and which includes a substrate bonding surface to which a substrate metal layer having an annular shape is fixed; and a light transmitting cap including a window portion containing glass and transmitting radiation light of the semiconductor light emitting element and a flange having a flange bonding surface to which an annular flange metal layer having a size corresponding to the substrate metal layer is fixed, and sealed and bonded to the substrate with a space housing the semiconductor light emitting element. The flange metal layer contains a first metal layer fixed to the flange and having a difference in the coefficient of linear thermal expansion from the flange within 1×10⁻⁶·K⁻¹ and a second metal layer formed on the first metal layer.

### BACKGROUND OF THE INVENTION

### 1. Field of the Invention

The present invention relates to a semiconductor light emitting device and particularly relates to a semiconductor light emitting device in which a semiconductor light emitting element radiating ultraviolet light is sealed inside.

### 2. Description of the Related Art

Conventionally, a semiconductor device is known in which a semiconductor element is sealed inside a semiconductor package. In the case of a semiconductor light emitting module, a transparent window member, such as glass, transmitting light from a light emitting element is bonded to a support on which the semiconductor light emitting element is placed and hermetically sealed.

For example, Patent Literatures (PTLS) 1, 2 disclose semiconductor light emitting modules in which a substrate provided with a recessed portion housing a semiconductor light emitting element and a window member are bonded to each other.

PTLS 3, 4 disclose ultraviolet light emitting devices in which a mounting substrate mounted with an ultraviolet light emitting element, spacers, and a cover formed of glass are bonded to one another.

Non-PTL 1 discloses a low-temperature sintering technique using copper nanoparticles.

### CITATION LIST

### Patent Literatures

PTL 1: JP 2015-18873 A

PTL 2: JP 2018-93137 A

PTL 3: JP 2016-127255 A

PTL 4: JP 2016-127249 A

### Non-Patent Literatures

Non-PTL 1: TOHOKU UNIVERSITY, MITSUI MINING & SMELTING CO., LTD., haps://www.mitsui-kinzoku.co.jp/wp-content/uploads/topics_190130.pdf, 2020-03-04

However, a further improvement has been demanded for the sealability and the bond reliability between the substrate and the window member. A semiconductor light emitting element radiating ultraviolet light, particularly an AlGaN-based semiconductor light emitting element, is susceptible to deterioration when the hermeticity is insufficient, and thus a semiconductor device mounted with the semiconductor light emitting element is demanded to have high hermeticity.

AlGaN-based crystals deteriorate by moisture. In particular, as the light emission wavelength becomes shorter, the Al composition increases and is more susceptible to deterioration. Thus, as a hermetic structure in which moisture does not enter the inside of a package housing the light emitting element, a structure of hermetically sealing between a substrate and a glass lid with a metal bonding material has been adopted. However, there has been a problem that the hermeticity is insufficient when used in a humid environment or water sections.

### SUMMARY OF THE INVENTION

The present invention has been made in view of the above-described respects. It is an object of the present invention to provide a semiconductor device having high reliability with which high hermeticity is maintained even in long-term use and high environmental resistance, such as moisture resistance and corrosion resistance.

A semiconductor light emitting device according to one embodiment of the present invention has:

a semiconductor light emitting element;

a substrate on which the semiconductor light emitting element is mounted and which includes a substrate bonding surface to which a substrate metal layer having an annular shape is fixed; and

a light transmitting cap including a window portion containing glass and transmitting radiation light of the semiconductor light emitting element and a flange having a flange bonding surface to which an annular flange metal layer having a size corresponding to the substrate metal layer is fixed, and sealed and bonded to the substrate with a space housing the semiconductor light emitting element, in which

the flange metal layer contains a first metal layer fixed to the flange and having a difference in the coefficient of linear thermal expansion from the flange within 1×10⁻⁶·K⁻¹ and a second metal layer formed on the first metal layer.

### BRIEF DESCRIPTION OF THE DRAWINGS

FIG. 1A is a plan view schematically illustrating the upper surface of a semiconductor light emitting device 10 according to a first embodiment.

FIG. 1B is a view schematically illustrating a side surface of the semiconductor light emitting device 10.

FIG. 1C is a plan view schematically illustrating the rear surface of the semiconductor light emitting device 10.

FIG. 1D is a view schematically illustrating the internal structure of the semiconductor light emitting device 10.

FIG. 1E is a perspective view schematically illustrating a ¼ part of a light transmitting cap 13 of the first embodiment.

FIG. 2A is a cross-sectional view schematically illustrating the cross section of the semiconductor light emitting device 10 along the A-A line of FIG. 1A.

FIG. 2B is a partially enlarged cross-sectional view illustrating the cross section of a bonded portion (W part) of FIG. 2A in an enlarged manner.

FIG. 3A is a cross-sectional view schematically illustrating a state before bonding of a substrate 11 and the light transmitting cap 13.

FIG. 3B is a cross-sectional view schematically illustrating a state after the bonding of the substrate 11 and the light transmitting cap 13.

FIG. 4A is a partially enlarged cross-sectional view illustrating the cross section of a bonded portion of the substrate 11 and a flange portion 13B in an enlarged manner.

FIG. 4B is a partially enlarged cross-sectional view illustrating the cross section of the bonded portion of the substrate 11 and the flange portion 13B in an enlarged manner.

FIG. 5 is a partially enlarged cross-sectional view illustrating a bonded portion of the substrate 11 and the flange portion 13B in a semiconductor light emitting device 30 according to a second embodiment in an enlarged manner.

FIG. 6A is a partially enlarged cross-sectional view illustrating a method for bonding a flange metal layer 21 and a substrate metal layer 12 to each other.

FIG. 6B is a partially enlarged cross-sectional view illustrating the method for bonding the flange metal layer 21 and the substrate metal layer 12 to each other.

FIG. 7 is a partially enlarged cross-sectional view illustrating a case where the substrate metal layer 12 is a Cu layer (metal layer 12M) of the same metal as that of a metal layer 21M which is the outermost surface metal layer of the flange metal layer 21.

FIG. 8A is partially enlarged cross-sectional view illustrating that a groove 11G is formed between a bonded portion 24 and wiring electrodes 14 to which a semiconductor light emitting element 15 is bonded.

FIG. 8B is a top view schematically illustrating the internal structure of the semiconductor light emitting device 30 according to the second embodiment and the upper surface of the substrate 11.

FIG. 9A is a cross-sectional view schematically illustrating the cross section of a semiconductor light emitting device 50 according to a third embodiment.

FIG. 9B is a partially enlarged cross-sectional view illustrating a W part where the substrate 11 and the light transmitting cap 13 having a flat plate shape are bonded to each other.

FIG. 10 is a partially enlarged cross-sectional view schematically illustrating the structure of a press ring 21A.

### DESCRIPTION OF THE PREFERRED EMBODIMENTS

Hereinafter, suitable examples of the present invention are described and may be modified and combined as appropriate. In the following description and the accompanying drawings, the description is given using the same reference signs attached to substantially the same or equivalent parts.

### First Embodiment

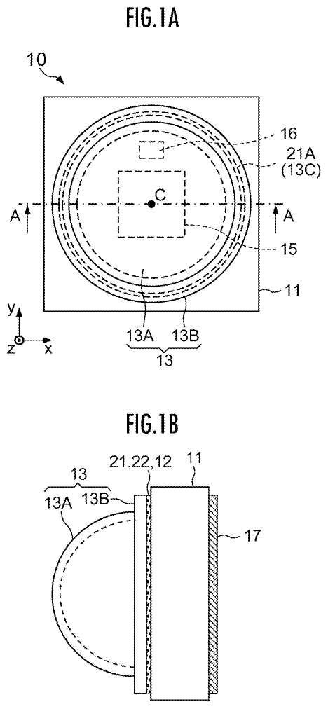

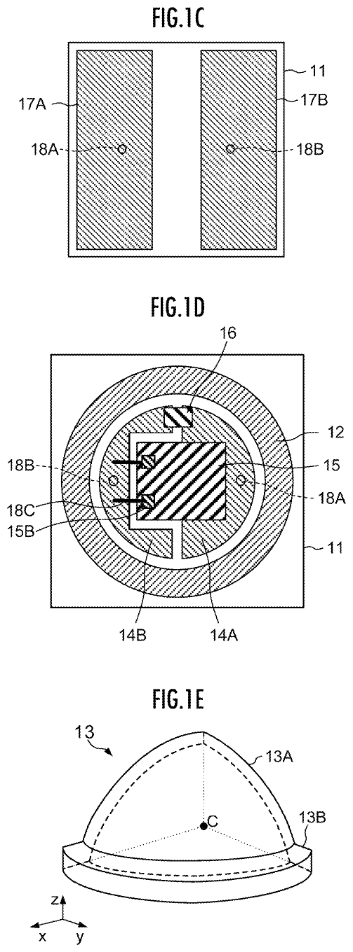

FIG. 1A is a plan view schematically illustrating the upper surface of a semiconductor light emitting device 10 according to a first embodiment of the present invention. FIG. 1B is a view schematically illustrating a side surface of the semiconductor light emitting device 10. FIG. 1C is a plan view schematically illustrating the rear surface of the semiconductor light emitting device 10. FIG. 1D is a view schematically illustrating the internal structure of the semiconductor light emitting device 10. FIG. 1E is a perspective view schematically illustrating a ¼ part of a light transmitting cap 13 of the first embodiment.

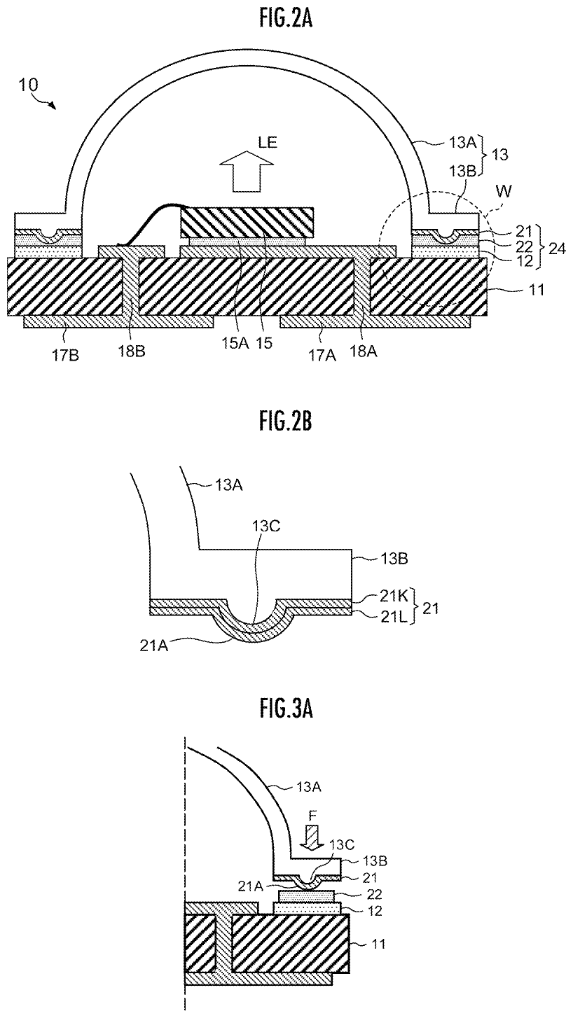

FIG. 2A is a cross-sectional view schematically illustrating the cross section of the semiconductor light emitting device 10 along the A-A line of FIG. 1A. FIG. 2B is a partially enlarged cross-sectional view illustrating the cross section of a bonded portion (W part) of FIG. 2A in an enlarged manner.

As illustrated in FIG. 1A and FIG. 1B, the semiconductor light emitting device 10 is formed by bonding a rectangular plate-like substrate 11 and the light transmitting cap 13 which is a semispherical light transmissive window containing glass. More specifically, an annular ring-shaped metal layer 12 (hereinafter also referred to as a substrate metal layer 12) is formed on the upper surface of the substrate 11 and bonded to the light transmitting cap 13.

The figures are illustrated assuming that the side surfaces of the substrate 11 are parallel to the x-direction and the y-direction and that the upper surface of the substrate 11 is parallel to the xy-plane.

As illustrated in FIG. 1E and FIG. 2A, the light transmitting cap 13 contains a semispherical dome portion 13A and a flange portion (or simply referred to as a flange) 13B provided at a bottom portion of the dome portion 13A.

FIG. 2B illustrates the flange portion 13B and a metal layer fixed to the flange portion 13B in an enlarged manner. The flange portion 13B has an annular-ring plate shape. A flange metal layer 21 is fixed to the bottom surface of the flange portion 13B, forming a flange bonding surface.

In more detail, the flange metal layer 21 contains a low thermal expansion metal layer 21K (first metal layer) fixed to the bottom surface of the flange portion 13B and a base metal/gold (Au) layer 21L (second metal layer) formed on the low thermal expansion metal layer 21K. The low thermal expansion metal layer 21K is, for example, a nickel-cobalt-iron (Ni—Co—Fe)-based low thermal expansion metal or Kovar (registered trademark). The base metal/gold layer 21L is, for example, a nickel/gold layer (Ni/Au layer) with the nickel as the base metal. More specifically, in the case of this example, the flange metal layer 21 is configured as a Kovar/Ni/Au layer. For example, as the strength of a bonded portion in which glass adjusted to have the same coefficient of thermal expansion as that of the Ni—Co—Fe metal and the Ni—Co—Fe metal are welded to each other, heat resistance to about several hundred degrees Celsius or more and high compressive stress resistance are imparted.

In the base metal/gold (Au) layer 21L, a barrier metal, such as Pd or Pt, may be inserted between the base metal and the gold (Au).

The flange metal layer 21 is bonded onto the substrate metal layer 12 by a cap bonding layer 22, thereby forming a bonded portion 24 and maintaining the hermeticity between the substrate 11 and the light transmitting cap 13.

The substrate 11 is a gas-impermeable ceramic substrate. For example, aluminum nitride (AlN) having high thermal conductivity and excellent hermeticity is used. AlN ceramic has a thermal conductivity of 150 to 170 (W/m·K) and a coefficient of thermal expansion of 4.5 to 4.6 (10⁻⁶·K⁻¹).

As a base material of the substrate 11, other ceramic excellent in hermeticity, such as alumina (Al₂O₃), is usable.

The light transmitting cap 13 contains a light transmissive glass transmitting radiation light from a semiconductor light emitting element 15 arranged in the semiconductor light emitting device 10. For example, quartz glass, borosilicate glass, or silicate glass is usable.

The bonded portion 24 of this example contains the AN substrate 11, which is hard but brittle, the flange metal layer 21, which has malleability, and the light transmitting cap 13, which is hard but brittle. The low thermal expansion metal layer 21K, such as Kovar (registered trademark), has ductility and functions as a stress buffer between the substrate 11 and the light transmitting cap 13.

By setting a difference in the coefficient of thermal expansion (coefficient of linear thermal expansion) of members to be bonded within 1 (×10⁻⁶·K⁻¹), a stress applied to the hermetic bonded portion 24 due to variations in the thermal history, ambient temperature, and the like caused by the drive of the light emitting element 15 can be reduced. More specifically, it is preferable that a difference in the coefficient of thermal expansion between the light transmitting cap 13 and the low thermal expansion metal layer 21K is set within 1 (×10⁻⁶·K⁻¹) or a difference in the coefficient of thermal expansion between the low thermal expansion metal layer 21K and the substrate 11 is set within 1 (×10⁻⁶·K⁻¹).

Specifically, a coefficient of thermal expansion a of the light transmitting cap 13 containing silicate glass is 5.8 (×10⁻⁶·K⁻¹), the coefficient of thermal expansion a of the Kovar (registered trademark) of the low thermal expansion metal layer 21K is 5.1 (×10⁻⁶·K⁻¹), and the coefficient of thermal expansion a of the AlN ceramic substrate 11 is 4.5 (×10⁻⁶·K⁻¹).

As a sealing gas in the semiconductor light emitting device 10, a dry nitrogen gas or a dry air with a low oxygen content is usable or a vacuum may be created inside.

As illustrated in FIG. 1D, the substrate 11 is provided thereon with a first wiring electrode (e.g., anode electrode) 14A and a second wiring electrode (e.g., cathode electrode) 14B, which are wiring electrodes in the semiconductor light emitting device 10 (hereinafter referred to as wiring electrodes 14 unless otherwise particularly distinguished). The semiconductor light emitting element 15, such as a light emitting diode (LED) or a semiconductor laser, is bonded onto the first wiring electrode 14A by a metal bonding layer 15A. A bonding pad 15B of the light emitting element 15 is electrically connected to the second wiring electrode 14B through a bonding wire 18C.

The light emitting element 15 is an aluminum gallium nitride (AlGaN)-based semiconductor light emitting element (LED) in which a semiconductor structure layer containing an n-type semiconductor layer, a light emitting layer, and a p-type semiconductor layer is formed. In the light emitting element 15, the semiconductor structure layer is formed (bonded) on (onto) a conductive support substrate (silicon: Si) through a reflective layer.

The light emitting element 15 is provided with an anode electrode (not illustrated) on the opposite surface (also referred to as the rear surface of the light emitting element 15) to a surface to which the semiconductor structure layer is bonded of the support substrate and is electrically connected to the first wiring electrode 14A on the substrate 11. Further, the light emitting element 15 is provided with a cathode electrode (pad 15B) on the opposite surface (also referred to as the front surface of the light emitting element 15) to which the support substrate is bonded of the semiconductor structure layer and is electrically connected to the second wiring electrode 14B through a bonding wire.

As the light emitting element 15, a type is also usable in which the semiconductor structure layer is provided on a growth substrate transmitting light radiated from the semiconductor structure layer besides the type in which the semiconductor structure layer is bonded to the support substrate as described above. For example, when the growth substrate is conductive, the rear surface of the growth substrate (surface opposite to the semiconductor structure layer) has a cathode electrode (not illustrated) and the upper surface of the semiconductor structure layer has an anode electrode (pad electrode for bonding wire connection). In the light emitting element 15, the cathode electrode is bonded onto the first wiring electrode 14A through the metal bonding layer 15A, and the pad electrode and the second wiring electrode 14B are electrically connected to each other through the bonding wire 18C.

When the growth substrate is insulated, the anode electrode is provided on the p-type semiconductor layer on the upper surface side of the semiconductor structure layer and the cathode electrode is provided on the n-type semiconductor layer. In the light emitting element, the anode electrode and the cathode electrode are bonded to the first wiring electrode 14A and the second wiring electrode 14B, respectively, through a metal bonding layer.

The light emitting element 15 is suitably an aluminum nitride-based light emitting element emitting ultraviolet light with a wavelength of 265 to 415 nm. Specifically, a light emitting element with a light emission center wavelength of 265 nm, 275 nm, 355 nm, 365 nm, 385 nm, 405 nm, or 415 nm was used.

The Al composition of semiconductor crystals constituting an aluminum nitride-based light emitting element radiating ultraviolet light (UV-LED element) is high and the light emitting element is easily oxidized and deteriorates by oxygen (O₂) or moisture (H₂O). When a bonding member containing organic matter, such as flux, is used for the bonding of the light emitting element 15 to the first wiring electrode 14A, carbides are deposited on the front surface of the light emitting element due to the residual flux (organic matter) in the bonding member. The carbide deposition can be prevented by mixing a slight amount of O₂ into the sealing gas and, at the same time, the mixed O₂ is inactivated before deteriorating the light emitting element 15, and therefore no problems occur.

On the substrate 11, a protective element 16, which is a Zener Diode (ZD), connected to the first wiring electrode 14A and the second wiring electrode 14B is provided and prevents electrostatic breakdown of the light emitting element 15.

As illustrated in FIG. 1C, the substrate is provided, on the rear surface 11, with a first mounting electrode 17A and a second mounting electrode 17B (hereinafter referred to as mounting electrodes 17 unless otherwise particularly distinguished) connected to the first wiring electrode 14A and the second wiring electrode 14B, respectively. Specifically, the first wiring electrode 14A and the second wiring electrode 14B are connected to the first mounting electrode 17A and the second mounting electrode 17B through metal vias 18A and 18B (hereinafter referred to as metal vias 18 unless otherwise particularly distinguished), respectively.

The wiring electrodes 14, the mounting electrodes 17, and the metal vias 18 are, for example, tungsten/nickel/gold (W/Ni/Au) or nickel chromium/gold/nickel/gold (NiCr/Au/Ni/Au).

Referring to FIG. 2A, the semiconductor light emitting device 10 is configured to be mounted on a wiring circuit board (not illustrated), and, by the application of a voltage to the first mounting electrode 17A and the second mounting electrode 17B, the light emitting element 15 emits light, and radiation light LE from the front surface (light extraction surface) of the light emitting element 15 is radiated to the outside through the light transmitting cap 13.

Next, the bonding of the substrate 11 and the flange portion 13B of the light transmitting cap 13 is described.

### (Light Transmitting Cap 13 and Flange Portion 13B)

First, as illustrated in FIG. 1A, FIG. 1B, and FIG. 1E, the light transmitting cap 13 includes the semispherical dome portion 13A, which is the window portion, and the flange portion 13B extending from the bottom portion (end portion) of the dome portion 13A. The flange portion 13B has a cylindrical outer shape. In more detail, the bottom surface of the flange portion 13B has an annular ring shape (center: C) concentric with the center of the dome portion 13A. More specifically, the outer edge (outer periphery) of the flange portion 13B is concentric with the inner edge (inner periphery) of the flange portion 13B.

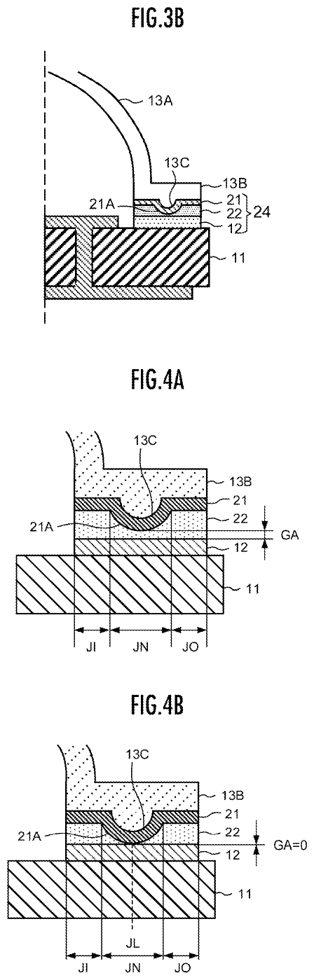

FIG. 3A is a cross-sectional view schematically illustrating a state before the bonding of the substrate 11 and the light transmitting cap 13. In a center portion in the radial direction (width direction) of an annular ring-shaped bottom surface of the flange portion 13B, a projection portion 13C is formed along the circumference of a circle concentric with the bottom surface (flange bonding surface) of the flange portion 13B. More specifically, the bottom surface of the flange portion 13B has a flat surface and the projection portion 13C projecting from the flat surface (hereinafter sometimes also referred to as annular ring-shaped projection portion). The cross-sectional shape perpendicular to the circumference of the concentric circle of the annular ring-shaped projection portion 13C is a semicircular shape, but is not limited thereto. For example, a rectangular shape or a trapezoidal shape may be acceptable.

### (Flange Metal Layer 21)

Further, the flange metal layer 21 is fixed to the bottom surface of the flange portion 13B as described above. The flange metal layer 21 is formed as a low thermal expansion metal/Ni/Au layer (with the Au layer being the outermost surface layer). By the projection portion 13C and the flange metal layer 21, a press ring 21A, which is an annular ring-shaped projection portion having a front surface coated with metal, is formed along the bottom surface of the flange portion 13B.

Such a flange metal layer 21 can be formed by welding a low thermal expansion metal molded into a shape corresponding to the bottom surface of the light transmitting cap 13 molded in advance at 900° C. to form the low thermal expansion metal layer 21K on the bottom surface, and then laminating the base metal/gold layer 21L on the front surface of the low thermal expansion metal layer 21K by electron beam deposition (EB deposition) or the like.

The formation of the press ring 21A is not limited to the structure described above. For example, it may be acceptable that the bottom surface of the flange portion 13B is formed into a flat surface, and then a low thermal expansion metal molded into a shape corresponding to the flat bottom surface and having an annular ring-shaped projection portion 21C is welded to the flat bottom surface of the flange portion 13B to form a low thermal expansion metal layer 21KC (first metal layer) as illustrated in FIG. 10.

In this case, the flange metal layer 21 can be formed by laminating the base metal/gold layer 21L on the front surface of the low thermal expansion metal layer 21KC by electron beam deposition (EB deposition) or the like.

More specifically, the annular ring-shaped projection portion 21C of the low thermal expansion metal layer 21KC (first metal layer) and the base metal/gold layer 21L formed on the low thermal expansion metal layer 21KC function as the press ring 21A which is an annular ring-shaped projection portion projecting from the flat bottom surface of the flange portion 13B having the annular ring shape and concentric with the annular ring. In the following description, the low thermal expansion metal layer 21K and the low thermal expansion metal layer 21KC welded to the flat bottom surface are referred to as the low thermal expansion metal layer 21K for the description, unless otherwise particularly distinguished.

### (Substrate Metal Layer 12)

As illustrated in FIG. 1A and FIG. 1D, the substrate metal layer 12 which is a metal ring body having an annular ring shape is fixed onto the substrate 11, and a substrate bonding surface is formed. In more detail, a bonded region of the substrate 11 to which the substrate metal layer 12 is fixed is flat and the substrate metal layer 12 has a shape (i.e., annular ring shape) and a size corresponding to those of the bottom surface of the flange portion 13B. Alternatively, the substrate metal layer 12 has a size including the entire of the flange metal layer 21 on the bottom surface of the flange portion 13B.

The substrate metal layer 12 is formed to be electrically insulated from the first wiring electrode 14A, the second wiring electrode 14B, the light emitting element 15, and the protective element 16 and surround them.

An annular ring-shaped bonding material is placed on the annular ring-shaped substrate metal layer 12 and a force F is applied to the light transmitting cap 13 for pressing while heating, thereby forming the cap bonding layer 22 having an annular ring shape, to which the light transmitting cap 13 is bonded, on the substrate 11 as illustrated in FIG. 3B.

The substrate metal layer 12 has, on the substrate 11, a structure in which tungsten/nickel/gold are laminated in this order (W/Ni/Au) or a structure in which nickel chromium/gold/nickel/gold are laminated in this order (NiCr/Au/Ni/Au).

The bonding material serving as the cap bonding layer 22 is a flux-free annular ring-shaped AuSn (gold-tin) sheet and one containing 20 wt % Sn (melting temperature: about 280° C.) was used, for example. On both the surfaces of the gold-tin alloy sheet, an Au (10 to 30 nm) layer can also be provided. The oxidation of an AuSn alloy can be prevented and stable bonding is enabled in a cap bonding step described later, and therefore the hermeticity can be improved. The Au layer is dissolved into the cap bonding layer 22 in melting and solidification (bonding).

### [Method for Manufacturing Light Emitting Device 10]

Hereinafter, a method for manufacturing the light emitting device 10 is described in detail and specifically.

### (Element Bonding Step)

First, a volatile solder paste for element bonding is applied onto the first wiring electrode 14A of the substrate 11. As the volatile solder paste, a volatile solder paste containing a flux with a boiling point around the melting point and gold-tin alloy (Au—Sn) fine particles was used. As the composition of the gold-tin alloy, one containing Au—Sn:22 wt % with a melting temperature of about 300° C. was used. This increases the melting temperature to be higher than that of the cap bonding layer 22 (Au—Sn: 20 wt %) to prevent the light emitting element 15 from falling out due to remelting of the metal bonding layer 15A bonding the light emitting element 15 during the cap bonding step. The particle size ranges from several nanometers to several tens of micrometers. The flux is organic matter containing, for example, rosins, alcohols, saccharides, esters, fatty acids, oils and fats, polymerized oils, surfactants, and the like which are carbonized with light (365 nm) of the light emitting element 15.

Next, the light emitting element 15 is placed on the volatile solder paste, the substrate is heated to 330° C. to melt and solidify the AuSn to bond the light emitting element 15 onto the first wiring electrode 14A. When the protective element 16 is to be mounted, the mounting is performed at the same time. At this time, most of the flux contained in the volatile solder paste is volatilized. The melting point of the metal bonding layer 15A thus formed is 330° C. or more because a rear surface electrode of the light emitting element 15 and the Au layer provided on the front surface of the first wiring electrode 14A are melted and solidified.

Next, the bonding pad 15B of an upper electrode of the light emitting element 15 and the second wiring electrode 14B are electrically connected by the bonding wire 18C (Au wire).

### (Cap Bonding Step)

The substrate 11 after the element bonding step and the light transmitting cap 13 are set in a cap bonding device. Next, the atmosphere of the substrate 11 and the light transmitting cap 13 is brought into a vacuum state and heated (annealed) at a temperature of 275° C. for 15 minutes.

Subsequently, the atmosphere of the substrate 11 and the light transmitting cap 13 is filled with 1 atm (101.3 kPa) of dry nitrogen (N₂) gas, which is a sealing gas. Next, the annular AuSn sheet (bonding material of the cap bonding layer 22) is placed on the substrate metal layer 12 of the substrate 11, and the light transmitting cap 13 is further placed thereon and pressed.

As illustrated in FIG. 3A, the temperature is increased to 300° C. while pressing the light transmitting cap 13 against the annular AuSn sheet. By the heating, the AuSn sheet is melted from a portion adhering to the press ring 21A toward the inside and the outside, and then solidified while melting a slight amount of the gold of the metal layers 12 and 21 or solidified by cooling (FIG. 3B). As described above, the substrate 11 and the light transmitting cap 13 are bonded to complete the semiconductor light emitting device 10.

For the annular AuSn sheet used in this step, an Au—Sn alloy containing 20 wt % Au—Sn (melting temperature: 280° C.) was used.

### [Bonded Portion of Substrate 11 and Flange Portion 13B]

By the bonding of the substrate 11 and the flange portion 13B described above, an annular ring-shaped region in which the press ring 21A has pressed and expanded the melted AuSn forms a narrowed junction region JN as illustrated in FIG. 4A. Further, an inner junction region JI and an outer junction region JO each having an annular ring shape as viewed from above (when viewed from a direction perpendicular to the flange portion 13B (z-direction)) are formed on the inside and the outside of the press ring 21A, i.e., on the inside and the outside of the narrowed junction region JN, respectively.

In this case, a top portion of the press ring 21A and the substrate metal layer 12 are bonded with a fixed interval (gap) GA over the entire periphery of the top portion of the press ring 21A. Hereinafter, for ease of description and understanding, the widths of the inner junction region JI, the narrowed junction region JN, and the outer junction region JO are described using the same signs (JI, JN, JO), respectively.

In the above-described bonding step, the press ring 21A can further press and expand the molten AuSn for pressing until the top portion of the press ring 21A abuts on the substrate metal layer 12. In this case, as illustrated in FIG. 4B, a circular connection line where the top portion of the press ring 21A and the substrate metal layer 12 contact each other, i.e., a circular connection portion JL where the bonding material (AuSn) is not present between the press ring 21A and the substrate metal layer 12, is formed, and a linear hermetic structure is formed in this portion.

More specifically, a circular hermetic structure is formed in which the top portion of the press ring 21A adheres to the substrate metal layer 12. In this case, in the circular connection portion JL, the interval (gap) GA between the top portion of the press ring 21A and the substrate metal layer 12 is 0.

As described above, the press ring 21A divides the cap bonding layer 22 into the three regions of the inner junction region JI, the narrowed junction region JN, and the outer junction region JO with the center of the press ring 21A as the boundary. The press ring 21A is a pressing portion for the bonding material and has functions of dividing and positioning the regions of the cap bonding layer 22.

Further, the press ring 21A has a function of preventing the overflow of the bonding material by controlling the interval (gap) GA between the top portion of the press ring 21A and the substrate metal layer 12.

The inner junction region JI and the outer junction region JO have a function as fillets for the press ring 21A and improve the shear strength, i.e., the fracture strength in the transverse direction (direction parallel to the bonding surface).

Further, in the case of Gap GA=0, the narrowed junction region JN acts as linear hermeticity where the top portion of the press ring 21A and the substrate metal layer 12 contact each other in a linear (circular) shape at the position JL (FIG. 4B), and the inner junction region JI and the outer junction region JO act as belt-like hermeticity.

Accordingly, a junction crystal portion can be reduced in thickness or eliminated and the area of the metal grain boundary surface, which causes leakage, can be minimized as much as possible, and thus the hermeticity yield can be improved.

The cap bonding layer 22 in the inner junction region JI and the outer junction region JO is melted and solidified toward the inside and the outside with the press ring 21A as the start point, and thus can prevent a stress intrinsic thereto and prevent the generation of gaps between the metal grain boundaries forming the bonding layer 22, and therefore can improve the hermeticity yield.

By adopting the narrowed junction region JN and forming the linear hermeticity or the belt-like hermeticity, a region where poor joint occurs can be reduced, and therefore the hermeticity can be improved. Further, the area of the metal grain boundary surface, which causes leakage, can be minimized, and therefore the hermeticity can be improved. In addition, the hermetic structures are provided in the narrowed junction region JN and on both sides thereof, and therefore high hermeticity reliability can be obtained. In addition, the formation of the gaps between the metals grain boundaries can be prevented, and therefore the hermeticity can be improved.

The press ring 21A is preferably configured so that the inner junction region JI and the outer junction region JO have an equal width (i.e., width JI=JO). More specifically, the press ring 21A is provided along a circle, the circumference of which passes through the center of the width of an annular ring of the flange metal layer 21 (flange bonding surface) having the shape of the annular ring.

The use of the low thermal expansion metal layer 21K for the flange metal layer 21 can protect the annular ring-shaped projection portion 13C of the flange portion 13B formed of glass and can prevent the annular ring-shaped projection portion 13C where force is concentrated in the cap bonding step from being chipped, for example, and causing poor hermeticity.

By a structure in which the bottom surface of the flange portion 13B is flattened and a low thermal expansion metal molded into a shape having the annular ring-shaped projection portion 21C is welded to the flat bottom surface of the flange portion 13B to provide the low thermal expansion metal layer 21KC, the light transmitting cap 13 can be strongly pressed against the substrate 11 and the tip of the press ring 21A can be brought into contact with the substrate metal layer 12 (GA=0).

The wall thickness of the dome portion 13A, which is the window portion of the light transmitting cap 13, can be entirely set to an equal thickness or increased in a center portion (convex meniscus lens) to narrow the light distribution or can be increased in the periphery (concave meniscus lens) to widen the light distribution.

### Second Embodiment

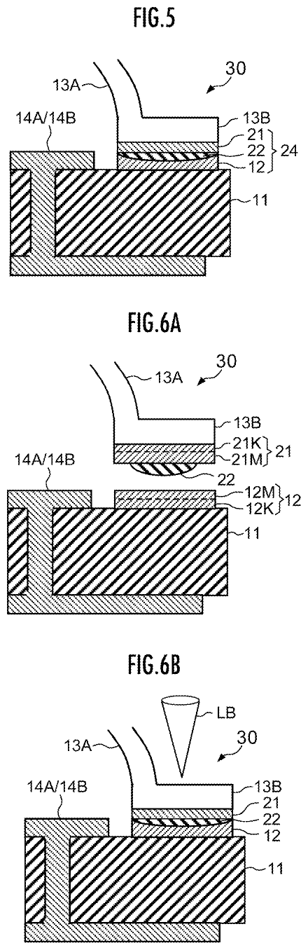

FIG. 5 is a partially enlarged cross-sectional view illustrating a bonded portion of the substrate 11 and the flange portion 13B in a semiconductor light emitting device 30 according to a second embodiment of the present invention in an enlarged manner.

The semiconductor light emitting device 30 of this embodiment is different from the semiconductor light emitting device 10 of the first embodiment described above in the bonded portion of the flange portion 13B and the substrate 11, and the other configurations are similar to those of the semiconductor light emitting device 10 of the first embodiment.

In the semiconductor light emitting device 30 of this embodiment, the flange metal layer 21 is bonded to the substrate metal layer 12 by the bonding layer 22 containing nanosized metal particles, thereby forming the bonded portion 24 and maintaining the hermeticity between the substrate 11 and the light transmitting cap 13.

### (Flange Metal Layer 21)

The bottom surface of the flange portion 13B has an annular ring shape, and the flange metal layer 21 is attached to the bottom surface of the flange portion 13B. The flange metal layer 21 contains the low thermal expansion metal layer 21K and a metal layer 21M (with the metal layer 21M being the outermost surface). More specifically, the flange metal layer 21 contains a Kovar (registered trademark) layer/Cu layer.

### (Substrate Metal Layer 12)

Referring to FIG. 1A and FIG. 1D again, the substrate metal layer 12 which is the metal ring body having an annular ring shape is fixed onto the substrate 11, and the substrate bonding surface is formed. The substrate metal layer 12 has a shape (i.e., annular ring shape) and a size corresponding to those of the bottom surface of the flange portion 13B. Alternatively, the substrate metal layer 12 may have a shape and a size including the entire of the flange metal layer 21 on the bottom surface of the flange portion 13B.

The substrate metal layer 12 contains a low thermal expansion metal layer 12K (third metal layer) and a metal layer 12M (fourth metal layer) (with the metal layer 12M being the outermost surface). More specifically, the substrate metal layer 12 contains a Kovar (registered trademark) layer/Cu layer. The substrate metal layer 12 enables the bonding of a Kovar (registered trademark)/Cu foil to the substrate 11, which is a ceramic substrate, by an Active Metal Brazing (AMB) method.

The outermost surface layer (metal layer 12M) of the substrate metal layer 12 is formed by a layer of the same metal (Cu in the case of this embodiment) as that of the outermost surface layer or a termination metal layer (metal layer 21M) of the flange metal layer 21.

### (Bonding Layer 22 and Bonding Method)

The bonding layer 22 of this embodiment is formed of copper nanoparticles. With reference to FIG. 6A and FIG. 6B, a method for bonding the flange metal layer 21 and the substrate metal layer 12 to each other is described.

As illustrated in FIG. 6A, a copper nanoparticle mixture liquid is applied to the lower surface of the flange metal layer 21 (front surface of the outermost surface metal layer) containing the low thermal expansion metal layer 21K and the outermost surface metal layer (Cu layer) 21M.

A copper nanoparticle deposit formed by the application is heated at 100 to 300° C. to remove a residual solvent (and a temporary binder). The copper nanoparticles after the solvent (temporary binder) have been removed are weakly bonded (weakly sintered) by heating in removing the binder.

Next, the substrate 11 and the light transmitting cap 13 are pressed against each other for adhesion and fixed to each other. At this time, the temporality bonded copper nanoparticles are crushed, and spread out while being made to enter the flange metal layer 21 and the substrate metal layer 12.

Subsequently, as illustrated in FIG. 6B, a laser beam LB is emitted from the outside of the glass surface of the flange portion 13B while cooling the rear surface of the substrate 11 so as not to remelt the metal bonding layer 15A of the light emitting element 15 to heat the flange metal layer 21, the copper nanoparticles (bonding layer 22 containing metal nanoparticles), and the substrate metal layer 12 to 200 and 500° C. to sinter the copper nanoparticles and form the hermetic cap bonding layer 22. The copper nanoparticles are sintered by heating for about 30 to 180 minutes in the case of a sintering temperature of 200° C. or for about a few minutes in the case of a sintering temperature of 500° C. When fired at a temperature equal to or lower than the remelting temperature (around 330° C.) of the element bonding member, such as Au—Sn, the entirety may be heated in an oven for sintering.

As described above, the flange metal layer 21 and the substrate metal layer 12 are bonded to each other by the bonding layer 22, which is a sintered layer containing nanosized metal particles, so that the hermetically sealing between the substrate 11 and the light transmitting cap 13 is maintained.

In the light emitting device 30 of this embodiment, the low thermal expansion metal layer 21K is used for the metal layer bonded to the flange portion 13B of the flange metal layer 21, and thus high bond strength with the flange portion 13B and a small difference in the coefficient of thermal expansion at high temperatures from the flange portion 13B can be achieved and the separation between the flange portion 13B and the low thermal expansion metal layer 21K does not occur even at high temperatures, which enables heating with a high-output laser beam from the side of the flange portion 13.

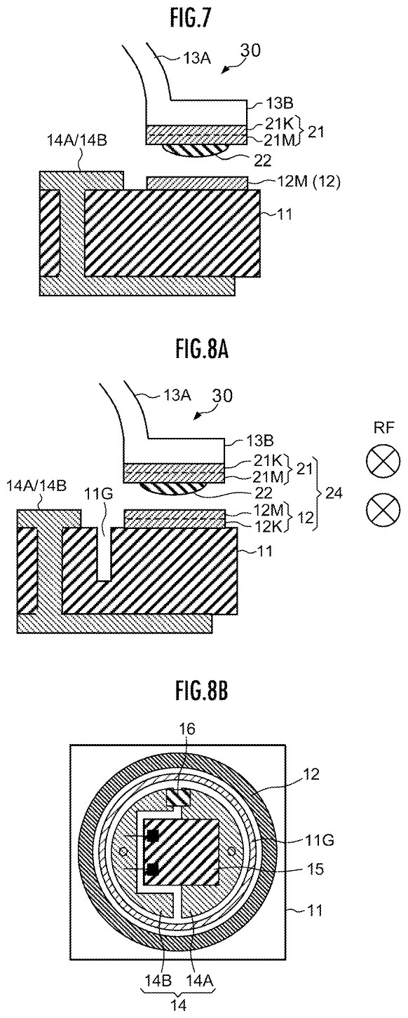

As illustrated in FIG. 7, it may be acceptable that the substrate metal layer 12 contains only the Cu layer (metal layer 12M) of the same metal as that of the metal layer 21M which is the outermost surface layer of the flange metal layer 21. In this case, the substrate metal layer 12 (i.e., metal layer 12M) can be formed by being bonded to the substrate 11 by the Active Metal Brazing (AMB) method, a DBC (Direct Bonding of Copper) method, or the like.

### (Bonding Layer 22 Containing Nanosized Metal Particles)

The nanosized metal particles of the bonding layer 22 are not limited to the copper nanoparticles and may also be other metals, such as gold (Au) or silver (Ag). When the gold (Au) layers are used for the outermost surface layer of the flange metal layer 21 and the outermost surface layer (metal layer 12M) of the substrate metal layer 12, gold nanoparticles, which are nanosized metal particles of the same metal as that of the outermost surface metal layer, are used.

For example, in the case of the substrate metal layer 12, Ni/Au plating may be applied onto the Cu layer bonded onto the substrate 11 by the AMB method or the like to form the metal layer 12M in which the outermost surface layer is the gold (Au) layer.

### [Modification of Second Embodiment]

FIG. 8A schematically illustrates a modification of the second embodiment in the case where the bonding layer 22 containing metal nanoparticles and the substrate metal layer 12 are heated using a high frequency induction heating device, for example, to sinter the metal nanoparticles and form a hermetical cap bonding layer (RF in the figure is an induction coil of the high frequency induction heating device). FIG. 8B is a top view schematically illustrating the internal structure of the semiconductor light emitting device 30 and the upper surface of the substrate 11.

In this modification, the flange metal layer 21 contains the low thermal expansion metal layer 21K and the metal layer (Cu layer) 21M and the substrate metal layer 12 contains the low thermal expansion metal layer 12K and the metal layer 12M as with the case illustrated in FIG. 6A.

A metal nanoparticle mixture liquid is applied to the lower surface of the flange metal layer 21, heated to 100 to 300° C. to remove the solvent (and a temporary binder), and then heated by the induction coils RF to 200 to 500° C. to sinter the metal nanoparticles and form the hermetic cap bonding layer 22.

In the light emitting device 30 of this modification, the low thermal expansion metal layer 21K is used for the metal layer bonded to the flange portion 13B of the flange metal layer 21, and thus high bond strength with the flange portion 13B and a small difference in the coefficient of thermal expansion at high temperatures from the flange portion 13B can be achieved and the separation between the flange portion 13B and the low thermal expansion metal layer 21K does not occur even at high temperatures, which enables high output induction heating.

In this modification, as illustrated in FIG. 8A and FIG. 8B, the substrate 11 is provided with a groove 11G formed in an annular shape for thermal insulation between the bonded portion 24 and a mounting portion where the semiconductor light emitting element 15 is bonded, i.e., between the bonded portion 24 and the wiring electrodes 14 to which the semiconductor light emitting element 15 is bonded. The transfer of the heat in sintering the metal nanoparticles by the induction coils RF, the laser beam LB, or the like to the bonded portion of the semiconductor light emitting element 15 and the like can be suppressed.

### Third Embodiment

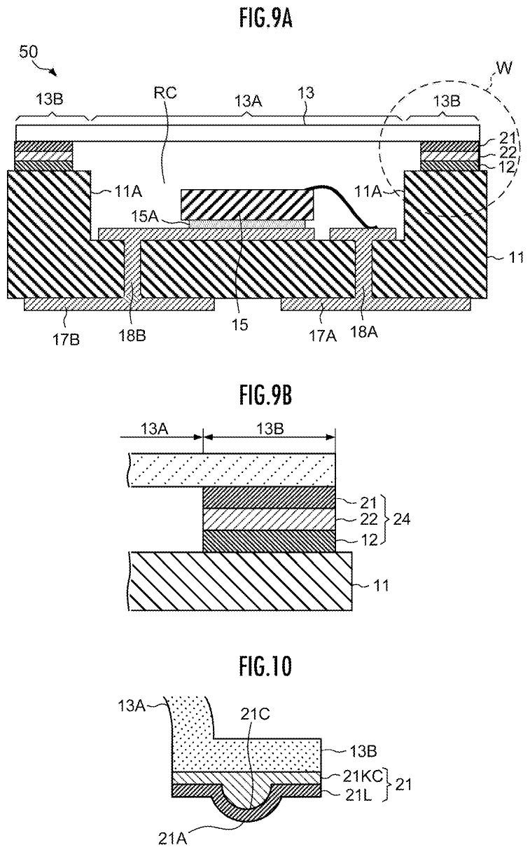

FIG. 9A is a cross-sectional view schematically illustrating the cross section of a semiconductor light emitting device 50 according to a third embodiment of the present invention. The semiconductor light emitting device 50 is different from the semiconductor light emitting devices 10, 30 of the above-described embodiments in that the light transmitting cap 13 is a disk-like flat plate. FIG. 9B is a partially enlarged cross-sectional view illustrating the W part where the substrate 11 and the light transmitting cap 13 are bonded to each other in an enlarged manner.

In more detail, an annular ring-shaped outer edge portion of the light transmitting cap 13 is the flange portion 13B and the inner side thereof is the window portion 13A which is a light transmitting portion. To the bottom surface of the flange portion 13B (i.e., annular ring-shaped outer peripheral portion of the bottom surface of the light transmitting cap 13), the annular ring-shaped metal layer 21 is fixed.

As illustrated in FIG. 9B, the flange metal layer 21 is bonded to the substrate metal layer 12 by the bonding layer 22 containing nanosized metal particles, thereby forming the bonded portion 24 and maintaining the hermeticity between the substrate 11 and the light transmitting cap 13.

In the semiconductor light emitting device 50 of this embodiment, the substrate 11 has a recessed portion RC, which is a space housing the semiconductor light emitting element 15 thereinside. In more detail, the substrate 11 is configured as a housing structure (frame structure) having the recessed portion RC of a cylindrical shape defined by a frame 11A formed to be erected in an outer peripheral portion of the substrate 11. To the flat top surface of the frame 11A, the light transmitting cap 13 is bonded. The semiconductor light emitting element 15 is provided to be bonded onto the substrate 11 at the bottom surface of the recessed portion RC by a bonding layer 15A.

According to the semiconductor light emitting device 50 of this embodiment, the frame 11A of the substrate 11 suppresses the transfer of the heat in sintering the metal nanoparticles by the high frequency induction heating, the laser beam LB, or the like to the bonded portion of the semiconductor light emitting element 15 and the like. Accordingly, it is possible to provide the semiconductor light emitting device having high hermeticity performance, free from the deterioration of the semiconductor light emitting element 15 and like and the bonded portion thereof by heat in hermetically sealing.

Further, in the semiconductor light emitting device 50 of this embodiment, the light transmitting cap 13 is formed by the disk-like flat plate, and thus easy processability, high bonding uniformity with the substrate 11, and a cost reduction can be achieved. The light transmitting cap 13 may also have a rectangular shape or a polygonal shape without being limited to the disk shape. Even when the bonding surface of the light transmitting cap 13 has a rectangular shape or a polygonal shape, sufficient hermetical bondability can be obtained when corner portions of the substrate metal layer 12 and the flange metal layer 21 are rounded (R-chamfered).

### Another Embodiment

The above-described embodiments describe the case where the flange metal layer 21, which is the bonding surface of the flange portion 13B, has the annular ring shape but the present invention is not limited thereto. For example, a configuration may be acceptable in which the flange metal layer 21 has a rectangular shape or an n-sided polygonal shape (where n is an integer of 3 or more), and the substrate metal layer 12 is bonded with a shape and a size corresponding to those of the flange metal layer 21.

When the substrate 11 has the recessed portion RC housing the semiconductor light emitting element 15, the recessed portion RC may have a rectangular columnar shape or a polygonal columnar shape or may have a rectangular columnar shape with R-chamfered corner portions depending on the shape of the substrate metal layer 12 and the flange metal layer 21.

As described above, the semiconductor light emitting device according to this embodiment can provide the semiconductor device having high reliability with which high hermeticity is maintained even in long-term use and high environmental resistance, such as moisture resistance and corrosion resistance.

### REFERENCE SIGNS LIST

10, 30 semiconductor light emitting device
11 substrate
11A frame
11G groove
12 substrate metal layer
12K low thermal expansion metal layer (third metal layer)
12M metal layer (fourth metal layer)
13 light transmitting cap
13A window portion
13B flange portion
13C, 13D projection portion
14, 14A, 14B wiring electrode
15 semiconductor light emitting element
21 flange metal layer
21A press ring
21K, 21KC low thermal expansion metal layer (first metal layer)
21M metal layer (second metal layer)
24 bonded portion
GA, GB gap
JI inner junction region
JN narrowed junction region
JO outer junction region
RC recessed portion

What is claimed is:

1. A semiconductor light emitting device comprising:
a semiconductor light emitting element;
a substrate on which the semiconductor light emitting element is mounted and which includes a substrate bonding surface to which a substrate metal layer having an annular shape is fixed; and
a light transmitting cap including a window portion containing glass and transmitting radiation light of the semiconductor light emitting element and a flange having a flange bonding surface to which an annular flange metal layer having a size corresponding to the substrate metal layer is fixed, and sealed and bonded to the substrate with a space housing the semiconductor light emitting element, wherein
the flange metal layer contains a first metal layer fixed to the flange and having a difference in a coefficient of linear thermal expansion from the flange within 1×10⁻⁶·K⁻¹ and a second metal layer formed on the first metal layer.

2. The semiconductor light emitting device according to claim 1, wherein
an outermost surface layer of the flange metal layer is any one of a gold (Au) layer, a silver (Ag) layer, and a copper (Cu) layer,
an outermost surface layer of the substrate metal layer is a metal layer of a same metal as metal of the outermost surface layer of the flange metal layer, and
the flange metal layer and the substrate metal layer are bonded by a bonding layer containing nanosized metal particles of the same metal.

3. The semiconductor light emitting device according to claim 1, wherein the first metal layer contains a nickel/cobalt/iron (Ni—Co—Fe)-based metal.

4. The semiconductor light emitting device according to claim 1, wherein the light transmitting cap contains quartz glass, borosilicate glass, or silicate glass.

5. The semiconductor light emitting device according to claim 1, wherein the substrate metal layer contains a nickel/cobalt/iron (Ni—Co—Fe)-based third metal layer formed on the substrate and a fourth metal layer formed on the third metal layer.

6. The semiconductor light emitting device according to claim 1, wherein the substrate metal layer is a metal layer fixed to the substrate and containing a same metal as metal of an outermost surface layer of the flange metal layer.

7. The semiconductor light emitting device according to claim 1, wherein the flange bonding surface has an annular ring shape and has a flat portion and a press ring which is an annular ring-shaped projection portion projecting from the flat portion and concentric with the annular ring of the flange bonding surface.

8. The semiconductor light emitting device according to claim 7, wherein
the flange bonding surface has a flat bottom surface, and
the first metal layer of the flange metal layer is welded onto the flat bottom surface and has a press ring which is an annular ring-shaped projection portion projecting from the flat bottom surface and concentric with the annular ring.

9. The semiconductor light emitting device according to claim 1, wherein the substrate has an annular groove formed between a bonded portion of the substrate and the flange and a mounting portion where the semiconductor light emitting element is bonded.

10. The semiconductor light emitting device according to claim 1, wherein
the substrate has a frame erected in an outer peripheral portion,
the space housing the semiconductor light emitting element is defined by the frame, and
the flange of the light transmitting cap is bonded to a top surface of the frame.

11. The semiconductor light emitting device according to claim 1, wherein the light transmitting cap has a flat plate shape.

12. The semiconductor light emitting device according to claim 1, wherein the semiconductor light emitting element is an aluminum nitride-based light emitting element.

13. The semiconductor light emitting device according to claim 12, wherein the semiconductor light emitting element is a light emitting element emitting ultraviolet light with a wavelength of 265 to 415 nm.

14. The semiconductor light emitting device according to claim 2, wherein the flange bonding surface has an annular ring shape and has a flat portion and a press ring which is an annular ring-shaped projection portion projecting from the flat portion and concentric with the annular ring of the flange bonding surface.

15. The semiconductor light emitting device according to claim 14, wherein
the flange bonding surface has a flat bottom surface, and
the first metal layer of the flange metal layer is welded onto the flat bottom surface and has a press ring which is an annular ring-shaped projection portion projecting from the flat bottom surface and concentric with the annular ring.
